(19) United States
(12) Patent Application Publication
(10) Pub. No.: US 2026/0162624 A1
(43) Pub. Date: Jun. 11, 2026

(54) DISPLAY DEVICE

(71) Applicant: LG Display Co., Ltd., Seoul (KR)

(72) Inventors: JunHyeok YANG, Paju-si (KR); YongChan PARK, Paju-si (KR); Hoiyong KWON, Paju-si (KR); JuHong KIM, Paju-si (KR); JiHun SONG, Paju-si (KR)

(73) Assignee: LG Display Co., Ltd., Seoul (KR)

(21) Appl. No.: 19/296,556

(22) Filed: Aug. 11, 2025

(30) Foreign Application Priority Data
Dec. 10, 2024 (KR) 10-2024-0182837

(51) Int. Cl. G09G 3/3275; G09G 3/3233; H10K 59/131

(52) U.S. Cl. CPC G09G 3/3275; G09G 3/3233; H10K 59/131; G09G 2300/0842

(57) ABSTRACT

Embodiments of the present disclosure provide a display device including a substrate having a display area for displaying images and a non-display area outside the display area. The device includes a source driving integrated circuit configured to supply data voltage to the display area, and a source film electrically connecting the display area and the source driving integrated circuit. A first line is disposed on the substrate within the non-display area, and a first pad electrically connected to the first line is positioned on the substrate. A second pad is spaced apart from the first pad in a first direction. A third pad is disposed to overlap the source film and electrically connects the first pad and the second pad, while remaining electrically disconnected from the source driving integrated circuit. This configuration allows sensing of electrical characteristics without involving the source driving integrated circuit.

### CROSS-REFERENCE TO RELATED APPLICATION

This application claims priority from Korean Patent Application No. 10-2024-0182837, filed on Dec. 10, 2024, which is hereby incorporated by reference for all purposes as if fully set forth herein.

### BACKGROUND

### Technical Field

Embodiments of the present disclosure relate to a display device.

### Description of the Related Art

The display device may include a plurality of data lines to which data voltages are supplied and a plurality of reference voltage lines to which reference voltages are supplied.

A data driving circuitry of the display device may sense the characteristic value of the driving transistor through a reference voltage line. Components for sensing the characteristic value of the driving transistor are required in the data driving circuitry.

### BRIEF SUMMARY

The disclosure relates to a display device including a pad structure that allows sensing of driving transistor characteristics before bonding the source film. The structure includes a reference pad connected to a reference voltage line, a reference shorting bar pad connected to a shorting bar for external voltage supply, and a connection reference pad that overlaps both the reference pad and the reference shorting bar pad. This configuration enables external test equipment to evaluate transistor characteristics without requiring sensing circuitry in the source driving integrated circuit. As a result, the source circuit is simplified, manufacturing cost is reduced, and defective panels can be screened prior to assembly.

The connection reference pad is formed to have a larger contact area than the other pads, helping reduce contact resistance. This structure is applicable to various self-emissive display technologies, such as organic light emitting diode and micro light emitting diode displays. By enabling electrical testing before the bonding of the source film, the design supports improved quality control, efficient defect detection, and reduced complexity in the overall circuit layout.

For example, various embodiments of the present disclosure may provide a display device including a reference pad to sense a driving transistor before bonding with a source film.

Embodiments of the present disclosure may provide a display device including a reference pad electrically connected to a shorting bar.

The tasks of the embodiments of the present disclosure are not limited to those mentioned in this specification, and other tasks not mentioned herein will be clearly understood by those skilled in the art from the following description.

Embodiments of the present disclosure may provide a display device comprising a substrate divided into a display area where an image is displayed and a non-display area outside the display area, a source driving integrated circuit supplying data voltage to the display area, a source film electrically connecting the display area and the source driving integrated circuit, a first line disposed on the substrate and positioned in the non-display area, a first pad positioned on the substrate and electrically connected to the first line, a second pad spaced apart from the first pad and disposed in a first direction from the first pad, and a third pad electrically connecting the first pad and the second pad, overlapping the source film, and electrically disconnecting the source driving integrated circuit.

Embodiments of the present disclosure may provide a display device comprising a substrate divided into a display area where an image is displayed and a non-display area outside the display area, a source driving integrated circuit supplying data voltage to the display area, a source film electrically connecting the display area and the source driving integrated circuit, a first pad overlapped the source film and spaced apart from the source driving integrated circuit, and a second pad, overlapped the source film and connected to the source driving integrated circuit via connecting line.

According to embodiments of the present disclosure, a display device including a first pad connected to a reference voltage line and a second pad connected to a shorting bar is provided.

According to embodiment of the present disclosure, a display device capable of sensing a characteristic value of a driving transistor by contacting a first pad connected to a reference voltage line is provided.

According to the embodiments of the present disclosure, by not disposing a component to sense a characteristic value of a driving transistor through a reference voltage line within a data driving circuitry, a data driving circuitry may be lightweight.

The effects of embodiments of the present disclosure are not limited to those mentioned above, and other effects not mentioned may be clearly understood by those skilled in the art from the description of the claims.

### BRIEF DESCRIPTION OF THE SEVERAL VIEWS OF THE DRAWINGS

The present disclosure will be more fully understood from a detailed description and accompanying drawings provided below, which are provided solely for explanatory purposes and are not intended to limit a scope of a present disclosure.

FIG. 1 is a system configuration diagram of a display device according to embodiments of the present disclosure.

FIG. 2 is an exemplary system configuration of a display device according to embodiments of the present disclosure.

FIG. 3 illustrates part of a display panel and a data driving circuitry according to embodiments of the present disclosure.

FIG. 4 illustrates a display panel connected to data driving circuitry according to embodiments of the present disclosure.

FIG. 5 is a cross-sectional view of S-S′ in FIG. 4 showing an exemplary cross-sectional structure of a display panel and data driving circuitry according to embodiments of the present disclosure.

FIG. 6 illustrates a connection relationship between a reference voltage line, a data line, and subpixels according to embodiments of the present disclosure.

FIG. 7 is an equivalent circuit diagram of an exemplary subpixel of a display device according to embodiments of the present disclosure.

FIG. 8 illustrates a portion of another display panel and another data driving circuitry according to embodiments of the present disclosure.

FIG. 9 is a cross-sectional view of A-A′ in FIG. 8 showing an exemplary cross-sectional structure of a display panel according to embodiments of the present disclosure.

FIG. 10 is a cross-sectional view of B-B′ in FIG. 8 showing an exemplary cross-sectional structure of a display panel according to embodiments of the present disclosure.

FIG. 11 is a cross-sectional view of C-C′ in FIG. 8 showing an exemplary cross-sectional structure of a data driving circuitry according to embodiments of the present disclosure.

FIG. 12 illustrates another display panel connected to another data driving circuitry according to embodiments of the present disclosure.

FIG. 13 is a cross-sectional view of D-D′ in FIG. 12 showing an exemplary cross-sectional structure of a display panel and a source film according to embodiments of the present disclosure.

FIG. 14 is a cross-sectional view of E-E′ in FIG. 12 showing an exemplary cross-sectional structure of a display panel and a source film according to embodiments of the present disclosure.

FIG. 15 is a cross-sectional view of F-F′ in FIG. 12 showing an exemplary cross-sectional structure of a display panel and a source film according to embodiments of the present disclosure.

FIG. 16 is a cross-sectional view of G-G′ in FIG. 12 showing an exemplary cross-sectional structure of a display panel and a source film according to embodiments of the present disclosure.

FIG. 17 illustrates other display panel and other data driving circuitry according to embodiments of the present disclosure.

FIG. 18 is a cross-sectional view of H-H′ in FIG. 17 showing an exemplary cross-sectional structure of a display panel according to embodiments of the present disclosure.

FIG. 19 is a cross-sectional view of I-I′ in FIG. 17 showing an exemplary cross-sectional structure of a data driving circuitry according to embodiments of the present disclosure.

FIG. 20 illustrates other display panel connected to other data driving circuitry according to embodiments of the present disclosure.

FIG. 21 is a cross-sectional view of J-J′ in FIG. 20 showing an exemplary cross-sectional structure of a source film and a display panel according to embodiments of the present disclosure.

FIG. 22 is a cross-sectional view of K-K′ in FIG. 20 showing an exemplary cross-sectional structure of a source film and a display panel according to embodiments of the present disclosure.

FIG. 23 is a cross-sectional view of L-L′ in FIG. 20 showing an exemplary cross-sectional structure of a source film and a display panel according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, it will be described various embodiments of the disclosure in detail with reference to the accompanying drawings.

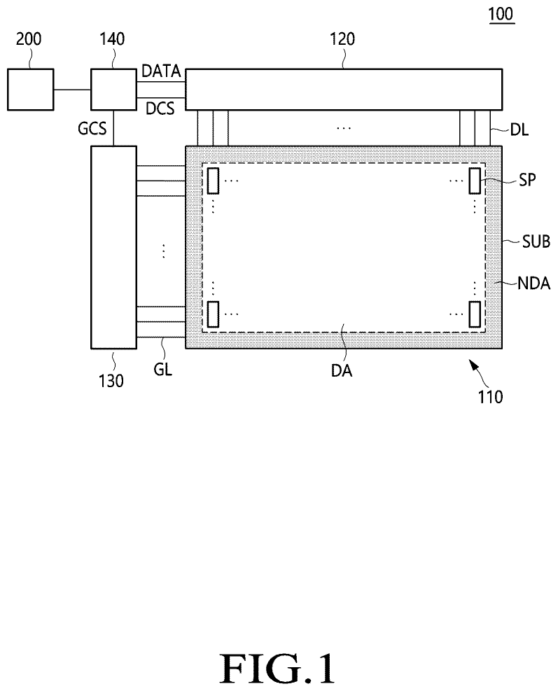

FIG. 1 is a system configuration diagram of a display device 100 according to embodiments of the present disclosure.

Referring to FIG. 1, the display device 100 according to the embodiments of the present disclosure may include a display panel 110 and display driving circuitry as components for displaying images. The display drive circuitry may be circuitry to drive the display panel 110. The display driving circuitry may include data driving circuitry 120, gate driving circuitry 130, and a controller 140, but the embodiments of the present disclosure are not limited thereto.

The display panel 110 may include a substrate SUB and a plurality of subpixels SP arranged on a substrate SUB.

The substrate SUB may include a display area DA and a non-display area NDA.

The display area DA is an area where an image can be displayed, and may also be referred to as an active area. A plurality of subpixels SP for image display may be disposed in the display area DA.

The non-display area NDA is an area where an image cannot be displayed, and may be an outer area of the display area DA. The non-display area NDA may also be referred to as a bezel (or bezel area). The non-display area NDA may include a pad area.

For example, the non-display areas NDA may include a first non-display area, a second non-display area, a third non-display area, and a fourth non-display area. The first non-display area may be positioned at the outer side of the display area DA in the row direction. The second non-display area may be positioned at the outer side of the display area DA in the row direction and may be positioned opposite to the first non-display area. The third non-display area may be positioned outside the display area DA in the column direction. The fourth non-display area may be positioned outside the display area DA in the column direction and opposite the third non-display area.

Among the first to fourth non-display areas, the fourth non-display area may include a pad area to which drive circuitry is connected or bonded (or laminated), and the first to third non-display areas may have a very small size, but the embodiments of the present disclosure are not limited thereto.

Another example is that the boundary area between the display area DA and the non-display area NDA is bent so that the non-display area NDA may be positioned at the bottom of the display area DA.

When a user looks at the display device 100 from the front, there may be little or no non-display area NDA visible to the user, but the embodiments of the present disclosure are not limited thereto.

The display device 100 according to the embodiments of the present disclosure may be a self-emissive display device in which the display panel 110 is self-emissive, but the embodiments of the present disclosure are not limited thereto. When the display device 100 according to the embodiments of the present disclosure is a self-emissive display device, each of a plurality of subpixels SP may include an light-emitting element.

For example, the display device 100 according to the embodiments of the present disclosure may be an organic light-emitting display device in which the light-emitting elements are configurated as organic light-emitting diodes (OLEDs). In another example, the display device 100 according to the embodiments of the present disclosure may be an inorganic light-emitting display device in which the light-emitting elements are configured as inorganic light-emitting diodes. In other examples, the display device 100 according to the embodiments of the present disclosure may be a quantum dot display device in which the light-emitting elements are quantum dots, which are semiconductor crystals that emit light on their own. In other examples, the display device 100 according to the embodiments of the present disclosure may be a micro LED display device or a mini LED display device.

The structure of each of a plurality of subpixels SP may differ depending on the type of display device 100. For example, when the display device 100 is a self-emissive display device in which subpixels SP emit light on their own, each subpixel SP may include a light-emitting element that emits light on its own, one or more transistors, and one or more capacitors, but the embodiments of the present disclosure are not limited thereto.

A plurality of signal lines may be disposed on a substrate SUB of a display panel 110 to drive a plurality of subpixels SP. For example, the plurality of signal lines may include a plurality of data lines DL to transmit data signals (also referred to as data voltages or image signals) and a plurality of gate lines GL to transmit gate signals (also referred to as scan signals).

For example, a plurality of data lines DL and a plurality of gate lines GL may cross each other. Each of the plurality of data lines DL may be disposed extending in a column direction, and each of the plurality of gate lines GL may be disposed extending in a row direction. According to embodiments of the present disclosure, the column direction and the row direction may be relative directions. For example, the column direction may be the row direction depending on the viewing perspective, and the row direction may be the column direction depending on the viewing perspective. Below, for the convenience of explanation, each of the plurality of data lines DL is disposed in the column direction, and each of the plurality of gate lines GL is disposed in the row direction, but the embodiments of the present disclosure are not limited thereto. In the embodiments of the present disclosure, the angle between the row direction and the column direction may be perpendicular (or 90 degrees) or may be an angle other than perpendicular. In addition, in the embodiments of the present disclosure, the row direction may be described as a first direction, and the column direction may be described as a second direction.

Data driving circuitry 120 may be circuitry for driving a plurality of data lines DL and may output data signals to a plurality of data lines DL.

Data driving circuitry 120 receives image data DATA in digital form from controller 140 and converts the received image data DATA into data signals (also referred to as data voltages) in analog form and outputs them to a plurality of data lines DL.

For example, data driving circuitry 120 may be connected to display panel 110 by tape automated bonding (TAB), a chip on glass (COG) or chip on panel (COP) method to connect to the bonding pads of the display panel 110, or may be configured as a chip on film (COF) method to connect to the display panel 110, and is not limited thereto.

Data driving circuitry 120 may be connected to one side (e.g., upper side or lower side) of display panel 110. In other examples, depending on the drive method, panel design method, etc., data driving circuitry 120 may be connected to both sides (e.g., upper and lower sides) of display panel 110, or to two or more of the four sides of display panel 110.

Data driving circuitry 120 may be connected to the periphery of a display area DA of a display panel 110, but in other examples, it may be disposed within a display area DA of a display panel 110.
gate drive circuitry 130 is circuitry to drive a plurality of gate lines GL and may output gate signals to a plurality of gate lines GL.

The gate driving circuitry 130 receives a first gate voltage corresponding to a turn-on voltage (also referred to as a turn-on level voltage) and a second gate voltage corresponding to a turn-off voltage (also referred to as a turn-off level voltage) together with various gate driving control signals (GCS), and for a predetermined time (e.g., one frame time), generate gate signals including a section having a first gate voltage and a section having a second gate voltage, and supply the generated gate signals to a plurality of gate lines GL. For example, the turn-on level voltage may be a high level voltage, and the turn-off level voltage may be a low level voltage. In another example, the turn-on level voltage may be a low level voltage, and the turn-off level voltage may be a high level voltage.

In a display device 100 according to embodiments of the present disclosure, the gate driving circuitry 130 may be of the gate-in-panel (GIP) type and may be built into the display panel 110, but embodiments of the present disclosure are not limited thereto. When the gate driving circuitry 130 is of the gate-in-panel type, during the manufacturing process of the display panel 110, the gate driving circuitry 130 may be formed on the substrate SUB of the display panel 110.

For example, the gate driving circuitry 130 may be disposed in a non-display area NDA of the display panel 110.

In another example, gate driving circuitry 130 may be disposed in the display area DA of the display panel 110. For example, gate driving circuitry 130 may be disposed in a first portion area (e.g., a left portion area or a right portion area) within the display area DA. In another example, gate driving circuitry 130 may be disposed in a first portion (e.g., a left portion or a right portion) of display area DA and a second portion (e.g., a right portion or a left portion) of display area DA. In another example, gate driving circuitry 130 may be disposed across entire area of display area DA.

When gate driving circuitry 130 is disposed in the display area DA of the display panel 110, gate driving circuitry 130 may be overlapped vertically with subpixels SP disposed in the display area DA. For example, the gate driving circuitry 130 may be overlapped vertically with light-emitting elements and transistors included in subpixels SP disposed in the display area DA. Gate driving circuitry 130 may be overlapped perpendicularly with a plurality of light-emitting elements and a plurality of transistors included in a plurality of subpixels SP disposed in a display area DA. Gate driving circuitry 130 may include a plurality of transistors. Each of a plurality of transistors included in gate driving circuitry 130 may include an active layer including a first semiconductor material, and each of a plurality of transistors included in subpixels SP may include an active layer including a second semiconductor material. For example, a first semiconductor material and a second semiconductor material may be substantially the same. In another example, a first semiconductor material and a second semiconductor material may be different from each other. For example, a first semiconductor material may be a silicon-based semiconductor material (e.g., LTPS (Low Temperature Poly Silicone)), and a second semiconductor material may be an oxide semiconductor material. For example, an active layer may be a semiconductor layer, but is not limited thereto.

Controller 140 is a device for controlling data driving circuitry 120 and gate driving circuitry 130, and may control driving timing for a plurality of data lines DL and driving timing for a plurality of gate lines GL.

Controller 140 may supply data driving control signal DCS to data driving circuitry 120 to control data driving circuitry 120, and supply gate driving control signal GCS to gate driving circuitry 130 to control gate driving circuitry 130.

Controller 140 may receive input image data from the host system 200 and supply image data DATA to data driving circuitry 120 based on the input image data.

Controller 140 may be configured to be a separate component from data driving circuitry 120, or may be integrated with data driving circuitry 120 to form an integrated circuitry.

Controller 140 may be a timing controller used in display technology, a control device that includes a timing controller and performs other control functions, a control device other than a timing controller, or circuitry within a control device. Controller 140 may be configured as various circuitry or electronic components, such as an integrated circuit (IC), a field programmable gate array (FPGA), an application specific integrated circuit (ASIC), or a processor, and is not limited thereto.

Controller 140 is mounted on a printed circuit board, flexible printed circuit, etc., and may be electrically connected to data driving circuitry 120 and gate driving circuitry 130 via the printed circuit board, flexible printed circuit, etc.

Controller 140 may transmit and receive signals with data driving circuitry 120 according to one or more predetermined interfaces. For example, interfaces may include LVDS (Low Voltage Differential Signaling) interfaces, EPI (Embedded Clock Point-Point Interface), and SPI (Serial Peripheral Interface), but are not limited thereto.

Display device 100 according to embodiments of the present disclosure may include a touch sensor, and touch sensing circuitry to sense the touch sensor to detect whether a touch was made by a touch object, such as a finger or pen, or to detect a touch position, in order to further provide touch sensing functionality in addition to video display functionality.

Touch sensing circuitry may include a touch driving circuitry that drives and senses a touch sensor to generate touch sensing data and output the touch sensing data, and a touch controller that can detect touch occurrence or detect a touch position using the touch sensing data.

Touch sensor may include a plurality of touch electrodes. Touch sensor may further include a plurality of touch lines for electrically connecting a plurality of touch electrodes and touch drive circuitry.

The touch sensor may be in the form of a touch panel outside the display panel 110 or may be inside the display panel 110. When the touch sensor is in the form of a touch panel outside the display panel 110, the touch sensor may be called an external type. When the touch sensor is external, the touch panel and the display panel 110 may be manufactured separately and combined during the assembly process. The external touch panel may include a substrate for the touch panel and a plurality of touch electrodes on the substrate for the touch panel.

When touch sensor is located inside display panel 110, touch sensor may be formed on substrate SUB together with signal lines and electrodes related to display driving during manufacturing process of display panel 110.

Touch driving circuitry may supply a touch driving signal to at least one of a plurality of touch electrodes and generate touch sensing data by sensing at least one of a plurality of touch electrodes.

Touch sensing circuitry may perform touch sensing using a self-capacitance sensing method or a mutual-capacitance sensing method.

When touch sensing circuitry performs touch sensing using a self-capacitance sensing method, touch sensing circuitry may perform touch sensing based on the capacitance between each touch electrode and a touch object (e.g., a finger, a pen, etc.). According to the self-capacitance sensing method, each of a plurality of touch electrodes may serve as both a driving touch electrode and a sensing touch electrode. touch driving circuitry may drive all or a part of a plurality of touch electrodes and may sense all or a part of a plurality of touch electrodes.

When touch sensing circuitry performs touch sensing using a mutual capacitance sensing method, touch sensing circuitry may perform touch sensing based on the capacitance between touch electrodes. According to the mutual-capacitance sensing method, a plurality of touch electrodes are divided into drive touch electrodes and sensing touch electrodes. touch drive circuitry may drive the drive touch electrodes and sense the sensing touch electrodes.

Touch driving circuitry and touch controller included in touch sensing circuitry may be configured as separate devices or as a single device. Furthermore, touch driving circuitry and data driving circuitry may be configured as separate devices or as a single device.

Display device 100 may further include a power supply circuitry that supplies various power sources to the display driving circuitry and/or touch sensing circuitry. The power supply circuitry may supply various voltages and power voltages related to display driving to the display driving circuitry or display panel 110.

Display device 100 according to embodiments of the present disclosure may be a mobile terminal such as a smartphone or tablet, or may be a monitor or television (TV) of various sizes, and is not limited thereto, but may be a display of various types and sizes capable of displaying information or images.

Display device 100 according to embodiments of the present disclosure may further include electronic devices such as a camera (image sensor) and a detection sensor. For example, the detection sensor may be a sensor that detects an object or a human body by receiving light such as infrared light, ultrasonic waves, or ultraviolet rays, but the embodiments of the present disclosure are not limited thereto.

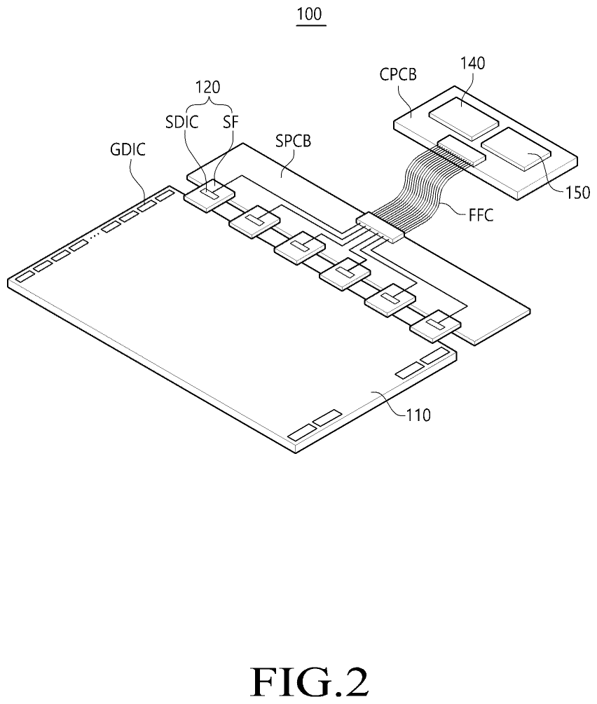

FIG. 2 is an exemplary system configuration of a display device 100 according to embodiments of the present disclosure.

Referring to FIG. 2, the display device 100 according to embodiments of the present disclosure is configured such that the data driving circuitry 120 is configured in a COF (Chip On Film) mode among various modes (TAB, COG, COF, etc.), and gate driving circuitry 130 is configured in a GIP (Gate In Panel) form from among various methods (TAB, COG, COF, GIP, etc.).

When gate driving circuitry 130 is configured to be a GIP, a plurality of gate driving integrated circuitry GDIC included in gate driving circuitry 130 may be directly formed in the bezel area of display panel 110. In this case, gate drive integrated circuitry GDIC may receive various signals (clock, gate high signal, gate low signal, etc.) necessary for generating scan signals through gate drive-related signal lines disposed in the bezel area.

Similarly, one or more source driving integrated circuits SDIC, included in the data driving circuitry 120 may be mounted on the source film SF, and one side of the source film SF may be electrically connected to the display panel 110. In addition, wiring for electrically connecting the source driving integrated circuit SDIC and the display panel 110 may be disposed on the upper side of the source film SF.

Such a display device 100 may include at least one source printed circuit board SPCB and a control printed circuit board CPCB for mounting control components and various electrical devices, for circuit connection between a plurality of source driving integrated circuit SDIC and other devices.

At this time, at least one source printing circuit board SPCB may be connected to the other side of the source film SF on which the source driving integrated circuit SDIC is mounted. In other words, the source film SF mounted with the source driving integrated circuit SDIC may be electrically connected to the display panel 110 on one side and electrically connected to the source printed circuit board SPCB on the other side.

Control printed circuit board CPCB may include controller 140 and power management circuitry 150. Controller 140 may control operation of data driving circuitry 120 and gate driving circuitry 130. Power management circuitry 150 may supply drive voltage or current to display panel 110, data driving circuitry 120, and gate driving circuitry 130, and may control the supplied voltage or current.

At least one source printed circuit board SPCB and control printed circuit board CPCB may be electrically connected through at least one connecting member, and the connecting member may be, for example, a flexible printed circuit, FPC, or a flexible flat cable, FFC. In addition, at least one source printed circuit board SPCB and a control printed circuit board CPCB may be configured as integrated into a single printed circuit board.

At this time, each subpixel SP arranged on the display panel 110 within the display device 100 may be composed of a light-emitting element and circuitry elements such as a driving transistor for driving the light-emitting element.

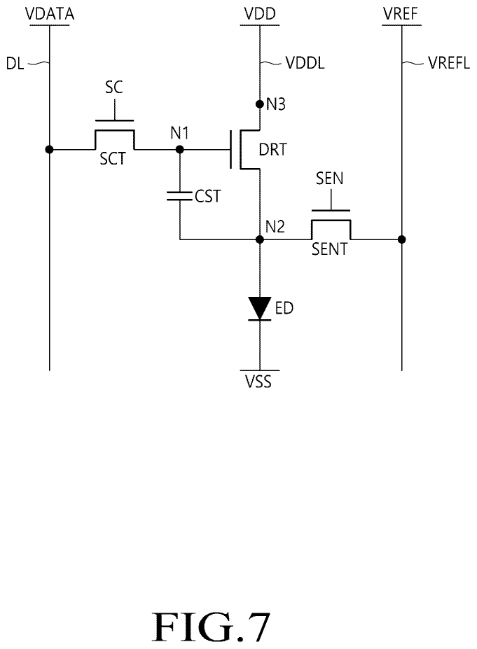

A type and number of the circuitry elements configuring each subpixel SP may be determined in various ways depending on the provided function and design method. An explanation of the subpixel SP is provided in FIG. 7.

Source driving integrated circuit SDIC of the display device 100 according to embodiments of the present disclosure may include various circuits (e.g., analog-to-digital converters) for sensing the driving transistors of the subpixels SP. Accordingly, the cost of manufacturing the source driving integrated circuit SDIC may increase. If the source driving integrated circuit SDIC does not include various circuits for sensing the driving transistors of the subpixels SP, the manufacturing cost of the source driving integrated circuit SDIC can be saved. Accordingly, a wiring structure of the display panel 110 and a pad arrangement of the source film SF may be changed.

Hereinafter, embodiments in which a source driving integrated circuit SDIC does not sense a driving transistor are described.

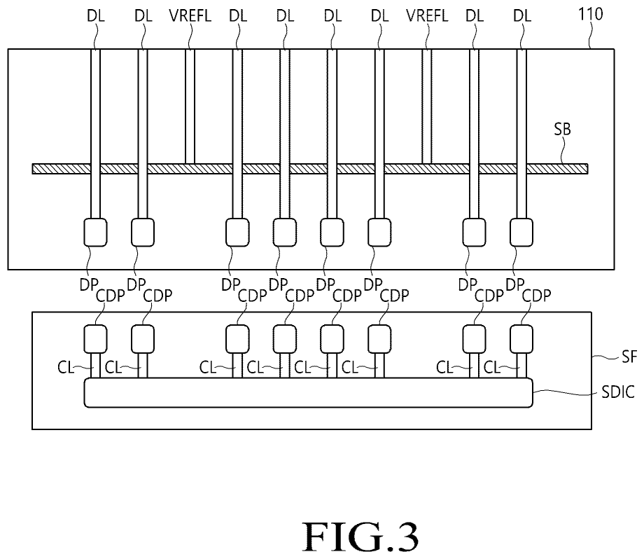

FIG. 3 illustrates part of a display panel 110 and a data driving circuitry 120 according to embodiments of the present disclosure.

Referring to FIG. 3, within the non-display area, NDA of the display panel, 110, a plurality of lines, (e.g., data line, DL) and a plurality of pads, (e.g., data pad, DP) electrically connected to the source film, SF may be disposed. For example, a plurality of data pads DP electrically connected to a plurality of reference voltage lines VREFL, a plurality of reference voltage lines VREFL, and a plurality of data lines DL may be disposed at the periphery of the display panel (110).

A plurality of reference voltage lines VREFL may be electrically connected to a shorting bar SB. Accordingly, the plurality of reference voltage lines VREFL may not be connected to the source driving integrated circuit SDIC.

A source film SF may be mounted with a source driving integrated circuit SDIC, a plurality of connecting lines CL, and a plurality of connecting data pads CDP. The source driving integrated circuit SDIC and the plurality of connecting lines CL may be electrically connected. The plurality of connecting lines CL may be electrically connected to the plurality of connecting data pads CDP. The source driving integrated circuit SDIC may output a data voltage to the connecting data pads CDP via the connecting lines CL. The data voltage may be a voltage that varied with time.

The following describes the structure connected to the data driving circuitry 120 and the display panel 110.

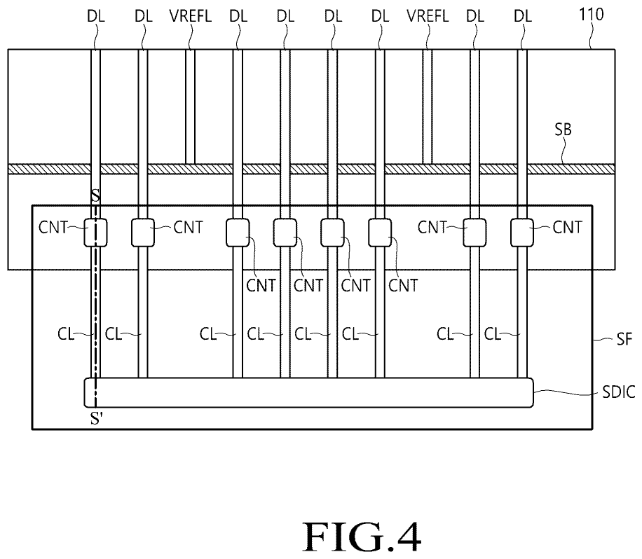

FIG. 4 illustrates a display panel 110 connected to data driving circuitry 120 according to embodiments of the present disclosure.

Referring to FIG. 4, a contact portion CNT may be disposed within the display panel 110, which is an area where a data pad DP and a connecting data pad CDP are electrically connected. within the contact portion CNT, the connecting data pad CDP may be electrically connected to the data pad DP of the display panel 110.

The reference voltage line VREFL connected to the shorting bar SB may be electrically disconnected from the source driving integrated circuit SDIC. Accordingly, the source driving integrated circuit SDIC may not perform sensing of the characteristic value (or characteristic parameter) of the driving transistor DRT via the reference voltage line VREFL, and may not include components for sensing the characteristic value (e.g., mobility, threshold voltage) of the driving transistor DRT.

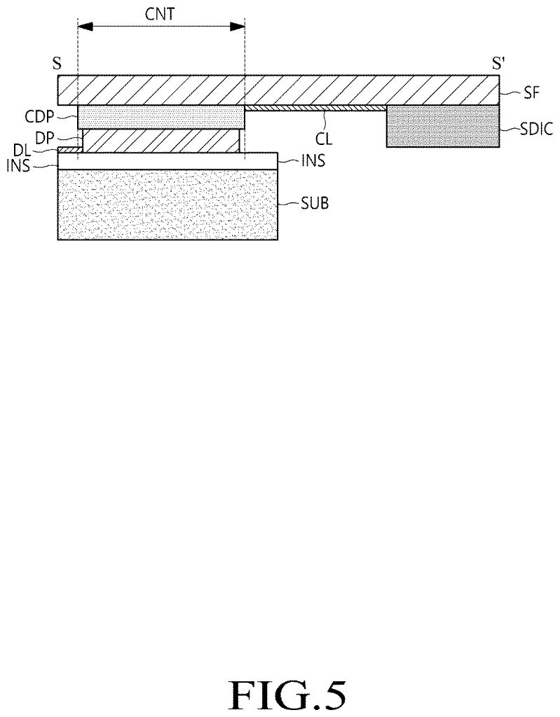

A detailed description of the connection structure within the contact portion CNT is examples in FIG. 5.

FIG. 5 is a cross-sectional view of S-S′ in FIG. 4 showing an exemplary cross-sectional structure of a display panel 110 and data driving circuitry 120 according to embodiments of the present disclosure.

Referring to FIG. 5, an insulation layer INS may be disposed on the substrate SUB. a data line DL and a data pad DP electrically connected to the data line DL may be disposed on the insulation layer INS. a connecting data pad CDP may be disposed on the data pad DP within the contact portion CNT. a source film SF may be disposed on the connecting data pad CDP. a connecting line CL electrically connected to the connecting data pad CDP and a source driving integrated circuit SDIC electrically connected to the connecting line CL may be mounted on the source film SF.

Accordingly, the voltage output from the source driving integrated circuit SDIC may be output to the connecting line CL. The voltage output to the connecting line CL may be output to the connecting data pad CDP. The voltage output to the connecting data pad CDP may be output to the data pad DP. The voltage output to the data pad DP may be output to the data line DL. The voltage output to the data line DL may be output to the subpixel SP.

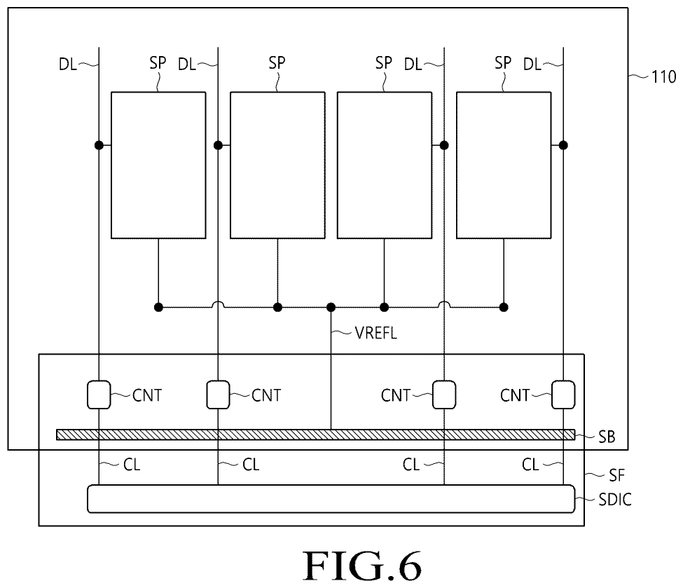

The connection relationship between the data line, DL, and the subpixel, SP, is illustrated in FIG. 6.

FIG. 6 illustrates a connection relationship between a reference voltage line VREFL, a data line DL, and subpixels SP according to embodiments of the present disclosure.

Referring to FIG. 6, the data voltage output from the source driving integrated circuit SDIC may be output to the data line DL through the contact portion CNT. Each of the plurality of data lines DL may supply the data voltage to the subpixels SP disposed in each row.

The shorting bar SB may receive a DC voltage as a reference voltage from an external source. For example, the shorting bar SB may receive a reference voltage from a power management circuit 150 of a control printed circuit board CPCB. The reference voltage may be a constant voltage over time.

The reference voltage may be output to the subpixel SP via the reference voltage line VREFL, which is electrically connected to the shorting bar SB. The reference voltage line VREFL may supply the reference voltage to the subpixels SP disposed in four rows.

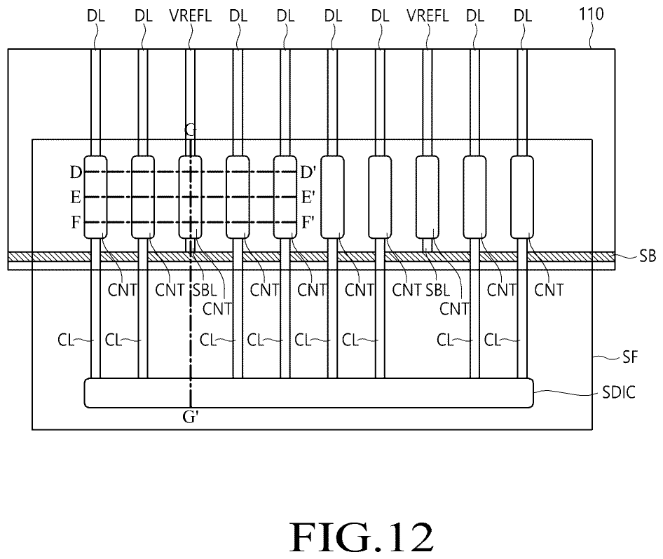

Within the display area DA, the connection relationship between the reference voltage line VREFL, the data line DL, and the subpixel SP may also apply to the display panel 110 described in FIGS. 12 to 23. In the non-display area NDA, unlike the reference voltage line VREFL in FIG. 6, which is electrically connected to the shorting bar SB without a pad, pads (e.g., reference pad, reference shorting bar pad, connection reference pad) described in FIGS. 12 to 23 may be electrically connected between the shorting bar SB and the reference voltage line VREFL.

Subpixel SP may control light emission through data voltage and reference voltage. The structure of subpixel SP is illustrated below.

FIG. 7 is an equivalent circuit diagram of an exemplary subpixel of a display device 100 according to embodiments of the present disclosure.

Referring to FIG. 7, in the display device 100 according to an embodiment of the present disclosure, the subpixel SP may include one or more transistors and capacitors, and an organic light-emitting diode may be disposed as a light-emitting element ED.

For example, a subpixel SP may include a driving transistor, DRT, a switching transistor SCT a sensing transistor SENT a storage capacitor CST and a light-emitting element ED.

The driving transistor DRT has a first node N1, a second node N2, and a third node N3. The first node N1 of the driving transistor DRT may be a gate node to which a data voltage VDATA is supplied from the data driving circuitry 130 through the data line DL when the switching transistor SCT is turned on. The second node N2 of the driving transistor DRT may be electrically connected to the anode electrode of the light-emitting element ED and may be a source node or a drain node. The third node N3 of the driving transistor DRT is electrically connected to the driving voltage line VDDL to which the subpixel driving voltage VDD is supplied, and may be a drain node or a source node.

At this time, during the display drive period, the subpixel drive voltage VDD required for displaying the image may be supplied to the drive voltage line VDDL. For example, the subpixel drive voltage VDD required for displaying the image may be 27 V.

The switching transistor SCT is electrically connected between the first node N1 of the driving transistor DRT and the data line DL, and operates in accordance with the scan signal SC supplied through the gate line GL connected to the gate node. In addition, when the switching transistor SCT is turned on, the data voltage VDATA supplied through the data line DL is transmitted to the gate node of the driving transistor DRT, thereby controlling the operation of the driving transistor DRT.

The sensing transistor SENT is electrically connected between the second node N2 of the driving transistor DRT and the reference voltage line VREFL, and operates according to the sense signal SEN supplied through the gate line GL connected to the gate node. When the sensing transistor SENT is turned on, the sensing reference voltage VREF supplied through the reference voltage line VREFL is transmitted to the second node N2 of the driving transistor DRT.

That is, by controlling the switching transistor SCT and the sensing transistor SENT, the voltage of the first node N1 and the second node N2 of the driving transistor DRT are controlled, so that a current for driving the light-emitting element ED may be supplied.

The gate nodes of the switching transistor SCT and the sensing transistor SENT may be connected to a single gate line GL or to different gate lines GL. Here, the structure where the switching transistor SCT and the sensing transistor SENT are connected to different gate lines GL is shown as an example, In this case, the switching transistor SCT and the sensing transistor SENT can be controlled independently by the scan signal SC and the sense signal SEN transmitted through different gate lines GL.

On the other hand, when the switching transistor SCT and the sensing transistor SENT are connected to a single gate line GL, the switching transistor SCT and the sensing transistor SENT can be controlled simultaneously by the scan signal SC or the sense signal SEN transmitted through the single gate line GL, and the aperture ratio of the subpixel SP may be increased.

Meanwhile, transistors disposed in subpixels, SP, may be made of not only n-type transistors but also p-type transistors. Here, an example of a case where they are made of n-type transistors is shown.

The storage capacitor CST is electrically connected between the first node N1 and the second node N2 of the driving transistor DRT, and maintains the data voltage VDATA during one frame.

The storage capacitors CST may be connected between the first node N1 and the third node N3 of the driving transistor DRT depending on the type of the driving transistor DRT. The anode electrode of the light-emitting element, ED, may be electrically connected to the second node, N2, of the driving transistor, DRT, and a base voltage, VSS, may be supplied to the cathode electrode of the light-emitting element, ED.

Here, the base voltage VSS may be the ground voltage or a voltage higher or lower than the ground voltage. In addition, the base voltage VSS may be variable depending on the drive state, and, for example, the base voltage VSS at the display drive timing may be set differently from the base voltage VSS at the sensing drive timing.

The structure of the subpixel SP described in the above example is a 3T (transistor) 1C (capacitor) structure, which is only an example for explanation, and may include one or more transistors or, in some cases, one or more capacitors. Alternatively, each of the multiple subpixels SP may have the same structure, or some of the multiple subpixels SP may have different structures.

The display device 100 according to an embodiment of the present disclosure senses a characteristic value of driving transistors DRT, such as threshold voltage or mobility, a method of measuring the current flowing by the voltage charged to a storage capacitor CST during a characteristic value sensing period of the driving transistor DRT may be used, which is referred to as current sensing.

That is, by measuring the current flowing due to the voltage charged to the storage capacitor CST during the characteristic value sensing period of the driving transistor DRT, it is possible to determine the characteristic value or change in the characteristic value of the driving transistor DRT within the subpixel SP.

At this time, the reference voltage line VREFL not only transmits the reference voltage VREF, but also acts as a sensing line for sensing the characteristic values of the driving transistors DRT in the subpixels SP. Therefore, the reference voltage line VREFL can be called a sensing line.

However, according to the embodiments of the present disclosure, the reference voltage line VREFL is not sensed while the source film SF is attached, and the characteristic value of the driving transistor DRT may be sensed by the pad connected to the reference voltage line VREFL coming into contact with the inspection device before the source film SF is attached.

Hereinafter, the disposition structure of a display device 100 for sensing characteristic values of a driving transistor DRT before a source film SF is bonded is described.

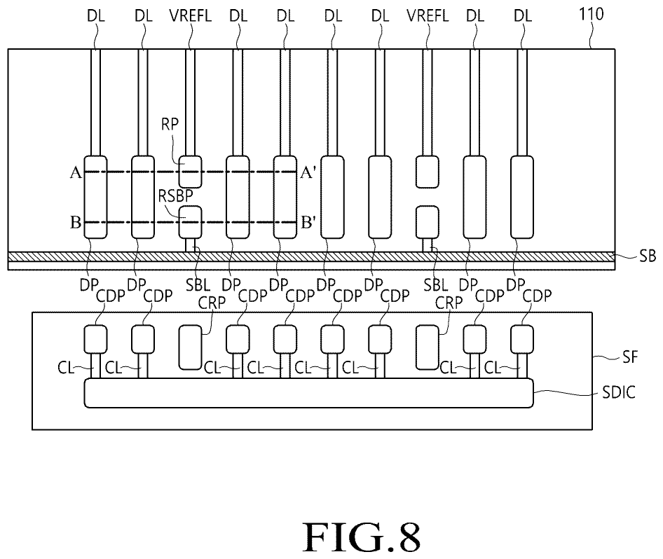

FIG. 8 illustrates a portion of another display panel 110 and another data driving circuitry 120 according to embodiments of the present disclosure.

Descriptions of the data line DL, data pad DP, connecting data pad CDP, connecting line CL, and source driving integrated circuit SDIC that are duplicated in FIG. 3 may be omitted.

Referring to FIG. 8, a plurality of reference voltage lines VREFL may be electrically connected to a plurality of reference pads RP, respectively. The reference shorting bar pad RSBP is spaced apart from the reference pad RP and may be electrically connected to the shorting bar SB via the shorting bar connecting line SBL.

The connection reference pad CRP is mounted on the source film SF and may be spaced apart from the source driving integrated circuit SDIC. The connection reference pad CRP may be formed longer in a vertical direction than sum of a length in the vertical direction of the reference pad RP and a length in the vertical direction of the reference shorting bar pad RSBP.

The shorting bar SB may be disposed between the data pad DP and the outermost part of the display panel 110. The shorting bar SB may be disposed between the reference pad RP and the outermost part of the display panel 110. The shorting bar SB may be disposed between the reference shorting bar pad RSBP and the outermost part of the display panel 110.

The reference shorting bar pad RSBP may receive a reference voltage VREF through the shorting bar connecting line SBL.

Before the source film SF is bonded to the display panel 110, the characteristic values of the driving transistors DRT may be sensed by contacting a plurality of data pads DP and a plurality of reference pads RP. Accordingly, even if the source driving integrated circuit SDIC does not perform sensing of the characteristic values of the driving transistors DRT, defective driving transistors DRT can be identified before the source film SF is bonded.

For example, a voltage to the reference pad RP to sense the characteristic value of the driving transistor DRT from the subpixel SP may be supplied. Before the source film SF is bonded to the reference pad RP, a voltage for sensing the characteristic value of the driving transistor DRT may be sensed by contacting a test device. The test device may determine whether the driving transistor DRT is defective by sensing the voltage for sensing the characteristic value of the driving transistor DRT.

Hereinafter, the cross section of the display panel 110 and the cross section of the source film SF before bonding are described.

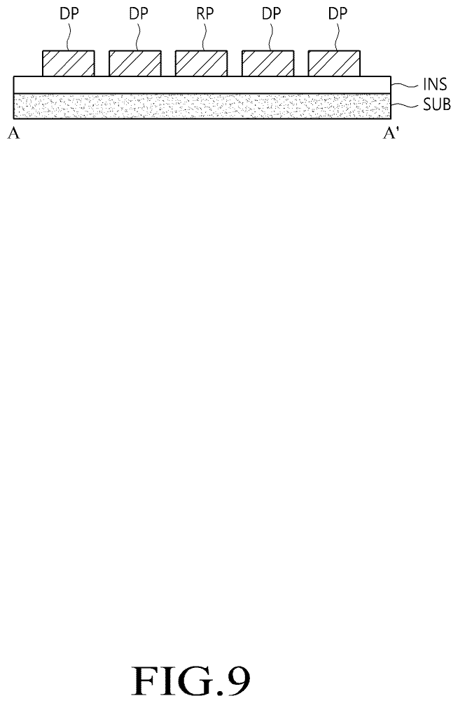

FIGS. 9 to 11 are cross-sectional views of the display panel 110 and the source film SF of FIG. 8 according to embodiments of the present disclosure.

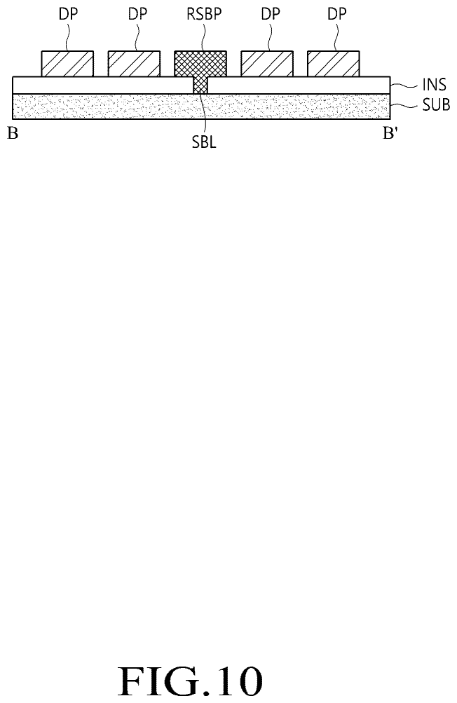

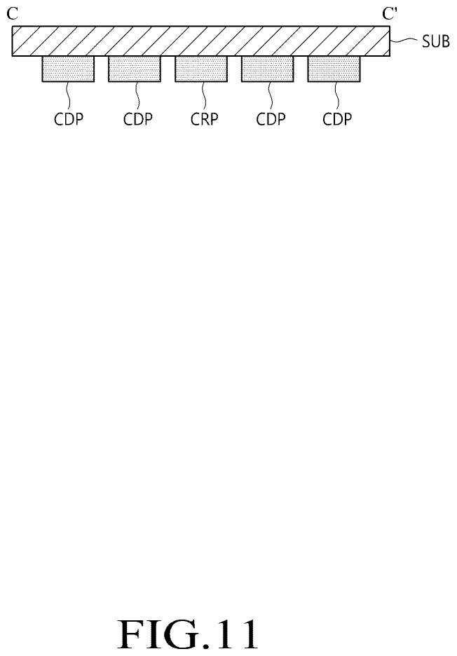

FIG. 9 is a cross-sectional view of A-A′ in FIG. 8 showing an exemplary cross-sectional structure of a display panel according to embodiments of the present disclosure. FIG. 10 is a cross-sectional view of B-B′ in FIG. 8 showing an exemplary cross-sectional structure of a display panel according to embodiments of the present disclosure. FIG. 11 is a cross-sectional view of C-C′ in FIG. 8 showing an exemplary cross-sectional structure of a data driving circuitry according to embodiments of the present disclosure.

Referring to FIG. 9, an insulation layer INS may be disposed on a substrate SUB. A plurality of data pads DP and reference pads RP may be disposed on the insulation layer INS. The reference pads RP may be disposed between two data pads DP and two other data pads DP.

Hereinafter, a cross-sectional view of the display panel 110 where the reference shorting bar pad 100 is positioned is described.

Referring to FIG. 10, an insulation layer INS is disposed on a substrate SUB. A plurality of data pads DP and reference shorting bar pad RSBP are disposed on the insulation layer INS. A shorting bar connecting line SBL connecting the reference shorting bar pads RSBP and the shorting bars SB may be disposed in a hole in the insulation layer INS.

The plurality of data pads DP in FIG. 10 may be the same as the plurality of data pads DP in FIG. 9. The reference shorting bar pad RSBP may be formed spaced apart from the reference pad RP in FIG. 9.

Referring to FIG. 11, a plurality of connecting data pads CDP and a connection reference pad CRP may be mounted on the source film SF.

FIG. 12 illustrates another display panel 110 connected to another data driving circuitry 120 according to embodiments of the present disclosure.

Descriptions of data lines DL, data pad DP, connecting data pad CDP, connecting lines CL, and source driving integrated circuit SDIC that are duplicated in FIG. 3 are omitted.

Referring to FIG. 12, a plurality of data pads DP and a plurality of connecting data pads CDP may be electrically connected within the contact portion CNT. A reference pad RP, a connection reference pad CRP, and a reference shorting bar pad RSBP may be electrically connected within the contact portion CNT.

The reference shorting bar pad RSBP in the contact portion CNT may be connected to the shorting bar SB through the shorting bar connecting line SBL. The shorting bar SB may be disposed on a layer different from the connecting line CL, the reference voltage line VREFL, and the data line DL. Accordingly, a shorts between the shorting bar SB and the connecting line CL, the reference voltage line VREFL, and the data line DL may be prevented.

In a display device 100 that does not sense the characteristic values of driving transistors DRT by a source driving integrated circuit SDIC, since a reference shorting bar pad RSBP is disposed between a shorting bar SB and a reference pad RP, and the reference pad RP and the reference shorting bar pad RSBP are connected through a connection reference pad CRP, the characteristic value of the driving transistor DRT may be sensed through contact with the reference pad RP and the data pad DP without a separate space being provided between a plurality of lines of the display panel 110.

Hereinafter, a connection section between the display panel 110 and the data driving circuitry 120 is described.

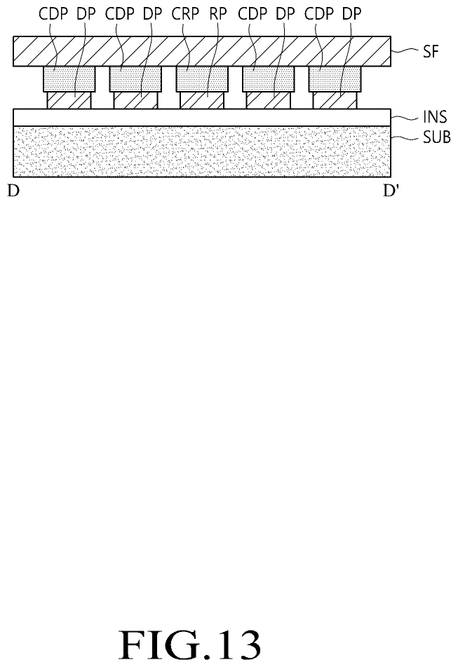

FIGS. 13 to 16 are cross-sectional views of the display panel 110 and the source film SF of FIG. 12 according to embodiments of the present disclosure.

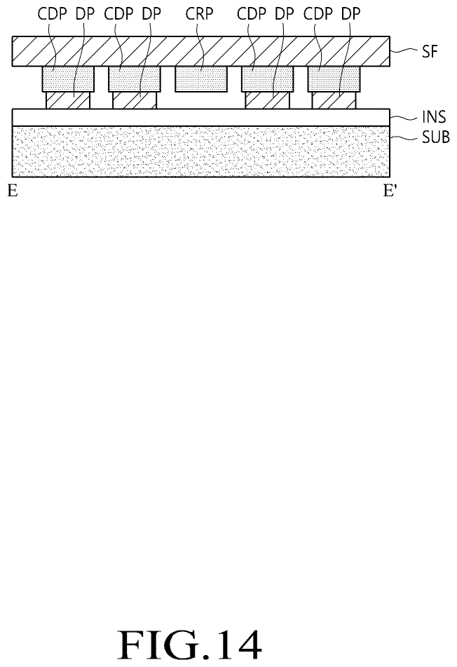

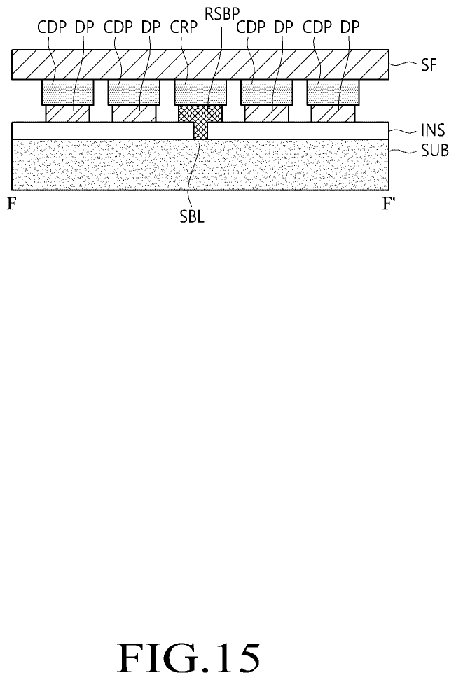

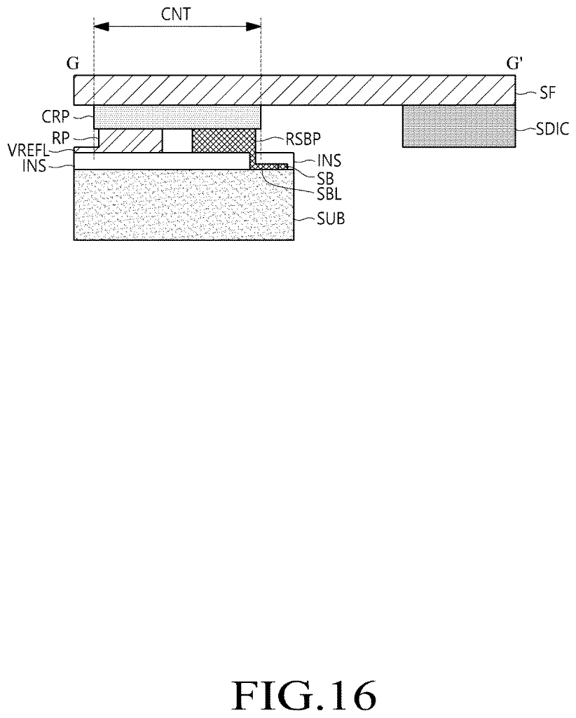

FIG. 13 is a cross-sectional view of D-D′ in FIG. 12 showing an exemplary cross-sectional structure of a display panel 110 and a source film SF according to embodiments of the present disclosure. FIG. 14 is a cross-sectional view of E-E′ in FIG. 12 showing an exemplary cross-sectional structure of a display panel 110 and a source film SF according to embodiments of the present disclosure. FIG. 15 is a cross-sectional view of F-F′ in FIG. 12 showing an exemplary cross-sectional structure of a display panel 110 and a source film SF according to embodiments of the present disclosure. FIG. 16 is a cross-sectional view of G-G′ in FIG. 12 showing an exemplary cross-sectional structure of a display panel 110 and a source film SF according to embodiments of the present disclosure.

Referring to FIG. 13, an insulation layer INS may be disposed on a substrate SUB. A reference pad RP and a plurality of data pads DP may be disposed on the insulation layer INS. A connection reference pad CRP may be disposed on the reference pad RP. A plurality of connecting data pads CDP may be disposed on each of the plurality of data pads DP.

Referring to FIG. 14, an insulation layer INS may be disposed on a substrate SUB. A plurality of data pads DP may be disposed on the insulation layer INS. In accordance with the separation of the reference pad RP and the reference shorting bar pad RSBP, there may be an area on the insulation layer INS where the reference pad RP and the reference shorting bar pad RSBP are not disposed. A plurality of connecting data pads CDP may be disposed on each of the plurality of data pads DP.

Referring to FIG. 15, an insulation layer INS may be disposed on a substrate SUB. A reference shorting bar pad RSBP and a plurality of data pads DP may be disposed on the Insulation Layer INS. A connection reference pad CRP may be disposed on the reference shorting bar pad RSBP. A plurality of connecting data pads CDP may be disposed on the plurality of data pads DP, respectively.

By overlapping the connection reference pad CRP on the reference shorting bar pad RSBP and the reference pad RP, the reference shorting bar pad RSBP and the reference pad RP may be electrically connected.

The shorting bar connecting line SBL connected to the reference shorting bar pad RSBP may be disposed in the hole of the insulation layer INS.

Referring to FIG. 16, an insulation layer INS may be disposed on a substrate SUB. A reference voltage line VREFL, a reference pad RP electrically connected to the reference voltage line VREFL, and a reference shorting bar pad RSBP spaced apart from the reference pad RP may be disposed on the insulation layer INS.

The shorting bar connecting line SBL, which is electrically connected to the reference shorting bar pad RSBP, is positioned on the substrate SUB and may be electrically connected to the shorting bar SB through hole in the Insulation Layer INS.

A connection reference pad CRP may be disposed on the reference pad RP and the reference shorting bar pad RSBP within the contact portion CNT. Accordingly, the reference voltage VREF supplied to the shorting bar SB may be supplied to the reference shorting bar pad RSBP, and the reference voltage VREF supplied to the reference shorting bar pad RSBP may be supplied to the connection reference pad CRP. The reference voltage VREF supplied to the connection reference pad CRP may be supplied to the reference pad RP. The reference voltage VREF supplied to the reference pad RP may be supplied to the reference voltage line VREFL. Accordingly, even if the reference voltage VREF is not supplied through the source driving integrated circuit SDIC, the reference voltage VREF may be supplied to the reference voltage line VREFL.

A source film SF may be disposed on a connection reference pad CRP. A source driving integrated circuit SDIC may be mounted on the source film SF. Since no connecting line CL is disposed between the connection reference pad CRP and the source driving integrated circuit SDIC, the connection reference pad CRP and the source driving integrated circuit SDIC may be spaced apart and electrically disconnected.

The reference shorting bar pad RSBP may be formed by removing at least a portion of the reference pad RP. As the contact area between the connection reference pad CRP, the reference shorting bar pad RSBP, and the reference pad RP is reduced, the pad contact resistance may increase. Accordingly, a pad disposition structure with a sufficient contact area between the reference shorting bar pad RSBP and the reference pad RP may be required.

Hereinafter, a display device 100 in which a reference shorting bar pad RSBP is disposed between a reference pad RP and a data pad DP is described.

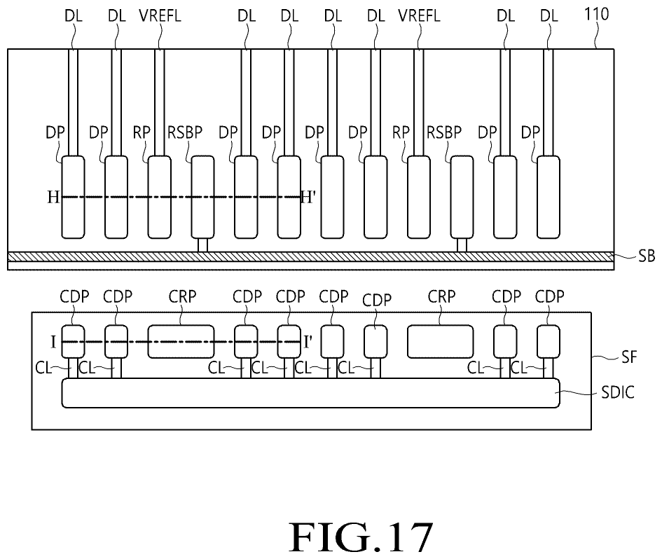

FIG. 17 illustrates other display panel 110 and other data driving circuitry 120 according to embodiments of the present disclosure.

Explanations of data lines DL, data pads DP, connecting data pads CDP, connecting lines CL, and source driving integrated circuits SDIC that are duplicated in FIG. 3 are omitted.

Referring to FIG. 17, the reference voltage line VREFL may be electrically connected to the reference pad RP. The reference shorting bar pad RSBP is spaced apart from the reference pad RP and may be electrically connected to the shorting bar SB via the shorting bar connecting line SBL. The reference shorting bar pad RSBP may be disposed between the reference pad RP and the data pad DP.

The connection reference pad CRP is mounted on the source film SF and may be spaced apart from the source driving integrated circuit SDIC. The connection reference pad CRP may be formed longer in the horizontal direction than the connecting data pad CDP. The connection reference pad CRP may be formed longer in the horizontal direction than a sum of a horizontal length of the reference pad RP and a horizontal length of the reference shorting bar pad RSBP. The connection reference pad CRP may be formed longer than the horizontal length of the reference pad RP. The connection reference pad CRP may be formed longer than the horizontal length of the reference shorting bar pad RSBP.

The shorting bar SB may be disposed between the data pad DP and the outermost part of the display panel 110. The shorting bar SB may be disposed between the reference pad RP and the outermost part of the display panel 110. The shorting bar SB may be disposed between the reference shorting bar pad RSBP and the outermost part of the display panel 110.

The reference shorting bar pad RSBP may receive a reference voltage VREF through the shorting bar connecting line SBL.

Before the source film SF is bonded to the display panel 110, characteristic values of driving transistors DRT may be sensed based on contact with a plurality of data pads DP and a plurality of reference pads RP. Accordingly, even if the source driving integrated circuit SDIC does not perform sensing of the characteristic values of the driving transistors DRT, defective driving transistors DRT can be identified before the source film SF is bonded.

For example, a voltage may be supplied to the reference pad RP to sense the characteristic value of the driving transistor DRT from the subpixel SP. Before the source film SF is bonded to the reference pad RP, a voltage for sensing the characteristic value of the driving transistor DRT may be sensed by contacting the inspection device. The inspection device may determine whether the driving transistor DRT is defective by sensing the voltage for sensing the characteristic value of the driving transistor DRT.

Hereinafter, the cross section of the display panel 110 and the cross section of the source film SF before bonding are described.

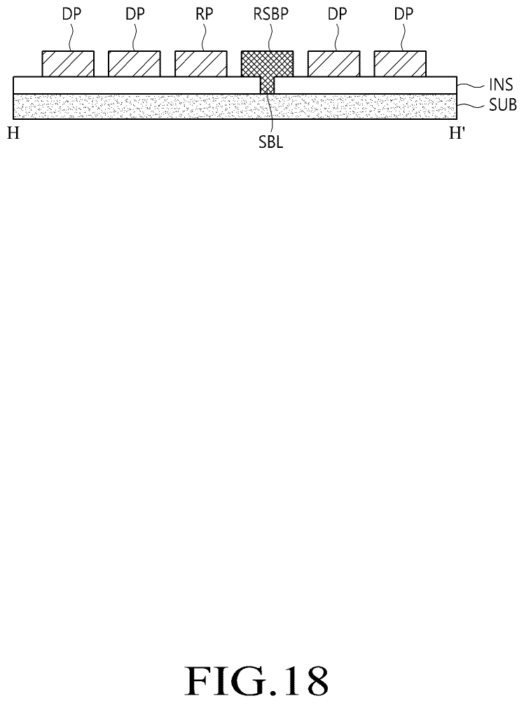

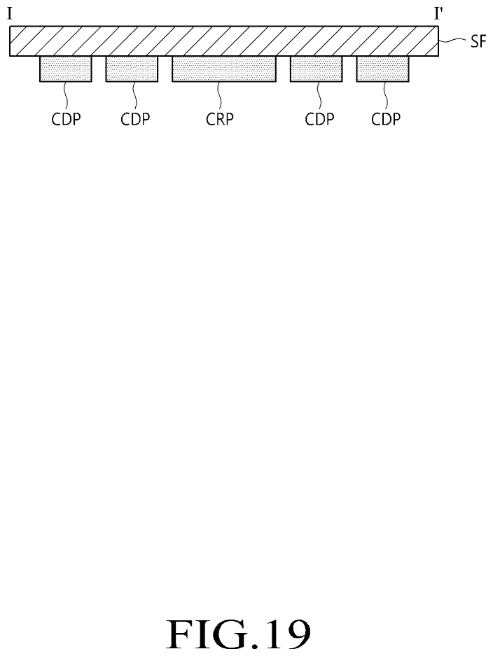

FIGS. 18 and 19 are cross-sectional views of the display panel 110 and source film SF according to the embodiment shown in FIG. 17.

FIG. 18 is a cross-sectional view of H-H′ in FIG. 17 showing an exemplary cross-sectional structure of a display panel 110 according to embodiments of the present disclosure. FIG. 19 is a cross-sectional view of I-I′ in FIG. 17 showing an exemplary cross-sectional structure of a data driving circuitry 120 according to embodiments of the present disclosure.

Referring to FIG. 18, an insulation layer INS may be disposed on a substrate SUB. A plurality of data pads DP, reference pads RP, and reference shorting bar pads RSBP may be disposed on the insulation layer INS. The reference pad RP may be disposed between the data pad DP and the reference shorting bar pad RSBP. Through the hole of the insulation layer INS, the shorting bar connecting line SBL may be disposed on the substrate SUB.

Referring to FIG. 19, a plurality of connecting data pads CDP and connection reference pad CRP may be mounted on the source film SF. The connection reference pads CRP may be formed larger than the connecting data pads CDP. Accordingly, additional space may be required on the source film SF.

Hereinafter, the display device 100 after the source film SF is bonded to the display panel 110 is described.

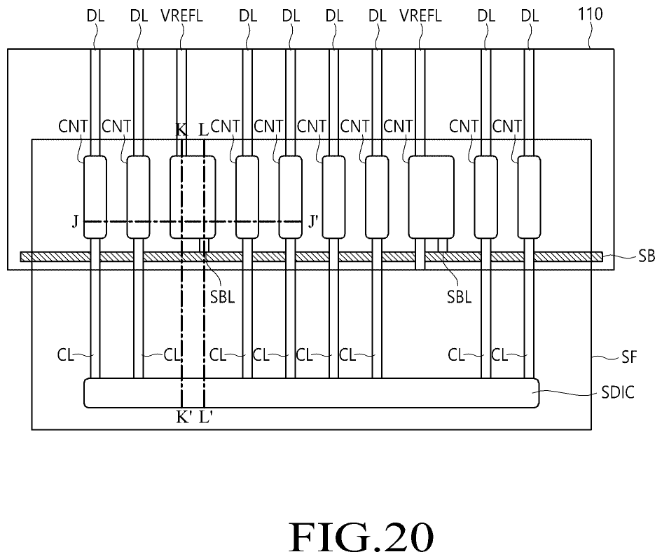

FIG. 20 illustrates other display panel 110 connected to other data driving circuitry 120 according to embodiments of the present disclosure.

Descriptions of data lines DL, data pads DP, connecting data pads CDP, connecting lines CL, and source drive integrated circuits SDIC that are duplicative of the descriptions in FIG. 3 are omitted.

Referring to FIG. 20, a plurality of data pads DP and a plurality of connecting data pads CDP may be electrically connected within the contact portion CNT. A reference pad RP, a connection reference pad CRP, and a reference shorting bar pad RSBP may be electrically connected within the contact portion CNT.

The reference shorting bar pad RSBP in the contact portion CNT may be connected to the shorting bar SB through the shorting bar connecting line SBL. The shorting bar SB may be disposed on a layer different from the connecting line CL, the reference voltage line VREFL, and the data line DL. Accordingly, a short between the shorting bar SB and the connecting line CL, the reference voltage line VREFL, and the data line DL may be prevented.

The reference shorting bar pad RSBP is disposed between the data pad DP and the reference pad RP, and the reference shorting bar pad RSBP may be spaced apart from the data pad DP and the reference pad RP, respectively. Accordingly, the display panel 110 may require additional space for disposing the reference shorting bar pad RSBP.

The following describes the connection cross section between the display panel 110 and the data driving circuitry 120.

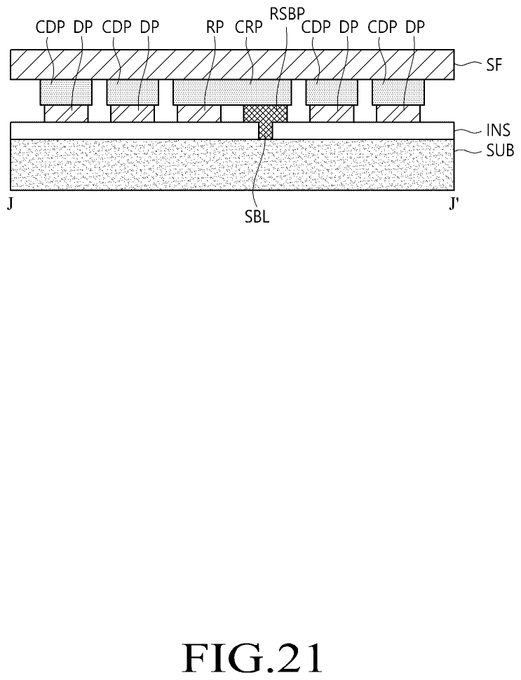

FIGS. 21 to 23 are cross-sectional views of the display panel 110 and the source film SF according to the embodiment shown in FIG. 20.

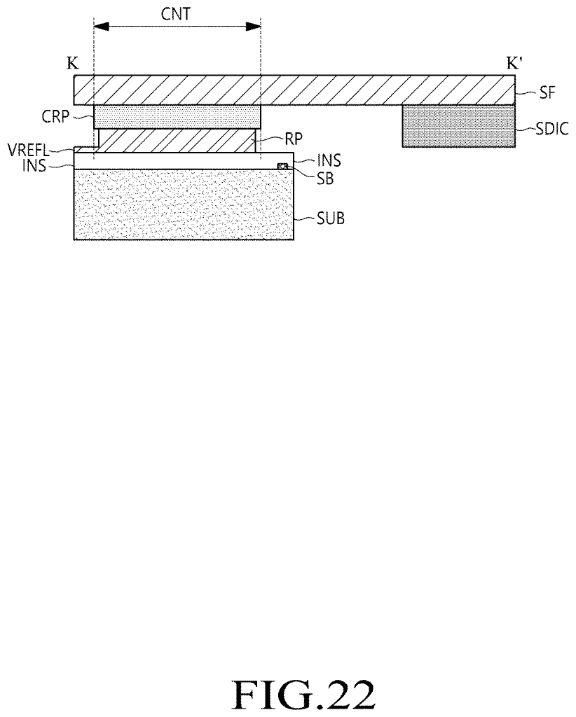

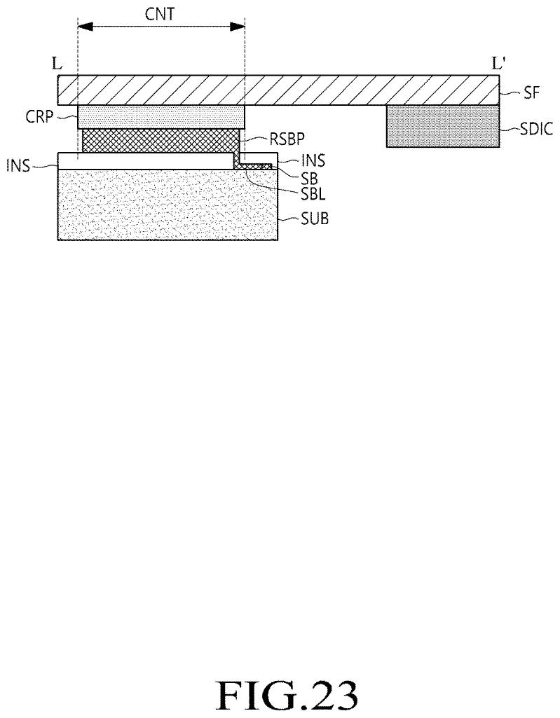

FIG. 21 is a cross-sectional view of J-J′ in FIG. 20 showing an exemplary cross-sectional structure of a source film SF and a display panel 110 according to embodiments of the present disclosure. FIG. 22 is a cross-sectional view of K-K′ in FIG. 20 showing an exemplary cross-sectional structure of a source film SF and a display panel 110 according to embodiments of the present disclosure. FIG. 23 is a cross-sectional view of L-L′ in FIG. 20 showing an exemplary cross-sectional structure of a source film SF and a display panel 110 according to embodiments of the present disclosure.

Referring to FIG. 21, an insulation layer INS may be disposed on a substrate SUB. A reference pad RP, a reference shorting bar pad RSBP, and a plurality of data pads DP may be disposed on the insulation layer INS. A connection reference pad CRP may be disposed on the reference pad RP and the reference shorting bar pad RSBP. A plurality of connecting data pads CDP may be disposed on the plurality of data pads DP. A source film SF may be disposed on the plurality of connecting data pads CDP and the connection reference pad CRP. A shorting bar connecting line SBL connecting a reference shorting bar pad RSBP and a shorting bar SB may be disposed in a hole of an insulation layer INS.

Referring to FIG. 22, an insulation layer INS may be disposed on a substrate SUB. A shorting bar SB may be disposed on the substrate SUB. The insulation layer INS may surround the shorting bar SB. A reference voltage line VREFL and a reference pad RP electrically connected to the reference voltage line VREFL may be disposed on the insulation layer INS. The reference pad RP may be disposed in spaced apart from the shorting bar SB.

A connection reference pad CRP may be disposed on a reference pad RP within a contact portion CNT. A source film SF may be disposed on the connection reference pad CRP. A source driving integrated circuit SDIC may be mounted on the source film SF. According to that the connecting line CL is not disposed between the connection reference pad CRP and the source driving integrated circuit SDIC, the connection reference pad CRP and the source driving integrated circuit SDIC may be spaced apart and electrically disconnected.

Hereinafter, the connection relationship between the source film SF and the reference shorting bar pad RSBP positioned between the reference pad RP and the data pad DP may be described.

Referring to FIG. 23, an insulation layer INS may be disposed on a substrate SUB. A shorting bar SB and a shorting bar connecting line SBL may be disposed on the substrate SUB. The shorting bar connecting line SBL may be electrically connected to a reference shorting bar pad RSBP through a hole in the insulation layer INS.

A reference shorting bar pad RSBP may be disposed on the insulation layer INS. A connection reference pad CRP may be disposed on the reference shorting bar pad RSBP within the contact portion CNT. Accordingly, the reference voltage VREF supplied to the shorting bar SB may be supplied to the reference shorting bar pad RSBP, and the reference voltage VREF supplied to the reference shorting bar pad RSBP may be supplied to the connection reference pad CRP. The reference voltage VREF supplied to the connection reference pad CRP may be supplied to the reference pad RP. The reference voltage VREF supplied to the reference pad RP may be supplied to the reference voltage line VREFL. Accordingly, even if the reference voltage VREF is not supplied through the source driving integrated circuit SDIC, the reference voltage VREF may be supplied to the reference voltage line VREFL.

A source film SF may be disposed on a connection reference pad CRP. A source driving integrated circuit SDIC may be mounted on the source film SF. Since the connecting line CL is not disposed between the connection reference pad CRP and the source driving integrated circuit SDIC, the connection reference pad CRP and the source driving integrated circuit SDIC may be spaced apart and electrically disconnected.

The reference shorting bar pad RSBP may be formed between the reference pad RP and the data pad DP with the same size as the reference pad RP. As the contact area between the connection reference pad CRP, the reference shorting bar pad RSBP, and the reference pad RP increases, the pad contact resistance may decrease. Accordingly, the size of the connection reference pad CRP mounted on the source film SF may be increased. As the size of the connection reference pad CRP increases, the size of the source film SF may also increase.

The display device according to the embodiments of the present disclosure may be described as follows.

A display device comprises a substrate divided into a display area where an image is displayed and a non-display area outside the display area, a source driving integrated circuit supplying data voltage to the display area, a source film electrically connecting the display area and the source driving integrated circuit, a first line disposed on the substrate and positioned in the non-display area, a first pad positioned on the substrate and electrically connected to the first line, a second pad spaced apart from the first pad and disposed in a first direction from the first pad, and a third pad electrically connecting the first pad and the second pad, overlapping the source film, and electrically disconnecting the source driving integrated circuit.

The display device a second line positioned on the substrate and spaced apart from the first line, a first data pad electrically connected to the second line, and a second data pad positioned on the first data pad and overlapping the source film

The second data pad is electrically connected to the source driving integrated circuit via a connecting line disposed on the source film.

The first line is supplied with a constant voltage over time, and the second line is supplied with a voltage that varies over time.

The first line is a reference voltage line to which a reference voltage is supplied, and the second line is a data line to which an image signal is supplied.

The second pad is disposed between the first pad and the first data pad.

The third pad is overlapped the first pad and the second pad.
a horizontal direction length of the third pad is longer than sum of a horizontal direction length of the first pad and a horizontal direction length of the second pad.

The display device comprises a shorting bar disposed in the non-display area, and a shorting bar connecting line electrically connecting the second pad and the shorting bar

The second pad is disposed between the first pad and a shorting bar electrically connected to the second pad.

The third pad is overlapped the first pad and the second pad.

A length in the vertical direction of the third pad is longer than sum of a length in the vertical direction of the first pad and a length in the vertical direction of the second pad.

The second pad is supplied with a reference voltage from the shorting bar via a shorting bar connecting line.

The display device comprises subpixel, including light-emitting element and driving transistor to drive the light-emitting element.

The subpixels are connected to the first line and the second line, supplied with a reference voltage from the first line, and supplied with the data voltage from the second line.
the first pad electrically connected to the first line is supplied with a voltage to sense the characteristic value of the driving transistor.

The display device comprises a substrate divided into a display area where an image is displayed and a non-display area outside the display area, a source driving integrated circuit supplying data voltage to the display area, a source film electrically connecting the display area and the source driving integrated circuit, a first pad overlapped the source film and spaced apart from the source driving integrated circuit, and a second pad, overlapped the source film and connected to the source driving integrated circuit via connecting line.

The display device comprises a first reference pad disposed on the substrate, a second reference pad disposed on the substrate, a first reference voltage line electrically connected to the first reference pad and the subpixel, a shorting bar connecting line electrically connected to the second reference pad, a data pad disposed on the substrate, a data line electrically connected to the data pad and the subpixel, and a shorting bar disposed in the non-display area and electrically connected to the shorting bar connecting line.

The second pad is overlapped with the data pad, and electrically connected to the data pad.

The first pad electrically connects the first reference pad and the second reference pad, and is overlapped with the first reference pad and the second reference pad.

The first reference voltage line and the data line are electrically connected to the subpixels disposed in the display area.

The shorting bar connecting line is electrically connected to the shorting bar.

A horizontal width of the first pad is longer than a horizontal width of the second pad.

A length in a vertical direction of the first pad is longer than sum of a length in the vertical direction of the first reference pad and a length in the vertical direction of the second reference pad.

A constant voltage over time is supplied to the shorting bar.

A voltage that varies with time is supplied to the connecting line.

In some embodiments, the display device may include a structure in which a first pad is electrically connected to a reference voltage line that supplies a reference voltage to a plurality of subpixels, and a second pad is electrically connected to a shorting bar configured to receive a reference voltage from an external power source. A third pad may be disposed to overlap both the first pad and the second pad in a plan view and may serve as a conductive element that electrically connects the first and second pads. The third pad may be electrically disconnected from the source driving integrated circuit and may be disposed on a source film.

In some embodiments, the third pad may be formed with a surface area greater than either the first or second pad to ensure stable contact and reduced contact resistance. The third pad may also be arranged in a stacked configuration over the first and second pads, with an insulating layer interposed between the third pad and any signal lines or terminals associated with the source driving integrated circuit.

The third pad structure may allow external test equipment to contact the first and second pads through the third pad before the source film is permanently bonded to the display panel. This enables electrical characteristics, such as the threshold voltage or mobility of a driving transistor within each subpixel, to be sensed without relying on sensing components within the source driving integrated circuit. Each subpixel may include a driving transistor and a light-emitting element, such as an organic light-emitting diode.

The second pad may be electrically connected to the shorting bar via a shorting bar connecting line, and in some embodiments, the shorting bar, the shorting bar connecting line, or both may be formed on a layer different from the reference voltage lines or the second pad to optimize routing and prevent electrical interference. The third pad may also be electrically isolated from all data lines and other signal lines associated with the source driving integrated circuit. In some configurations, the shorting bar may be disposed nearer to the outer edge of the display panel than either the first or second pad to facilitate access and separation from active circuitry.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be supplied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprises:
a substrate having a display area where an image is displayed and a non-display area adjacent to the display area;
a source driving integrated circuit configured to supply data voltage to the display area;
a source film electrically connected to the display area and the source driving integrated circuit;
a first line on the substrate and positioned in the non-display area;
a first pad on the substrate and electrically connected to the first line;
a second pad spaced apart from the first pad and disposed in a first direction from the first pad; and
a third pad electrically connected to the first pad and the second pad,
wherein the third pad overlaps the source film, and is electrically disconnected from the source driving integrated circuit.

2. The display device of claim 1, further comprising:
a second line on the substrate and spaced apart from the first line;
a connecting line on the source film;
a first data pad electrically connected to the second line; and
a second data pad on the first data pad and overlapping the source film,
wherein the second data pad is electrically connected to the source driving integrated circuit via the connecting line on the source film.

3. The display device of claim 2,
wherein the first line is supplied with a constant voltage over time, and the second line is supplied with a voltage that varies over time.

4. The display device of claim 2,
wherein the first line is a reference voltage line to which a reference voltage is supplied, and the second line is a data line to which an image signal is supplied.

5. The display device of claim 2,
wherein the second pad is between the first pad and the first data pad.

6. The display device of claim 5,
wherein the third pad overlaps the first pad and the second pad.

7. The display device of claim 6,
wherein a horizontal direction length of the third pad is longer than a sum of a horizontal direction length of the first pad and a horizontal direction length of the second pad.

8. The display device of claim 7, further comprising:
a shorting bar disposed in the non-display area, and a shorting bar connecting line electrically connecting the second pad and the shorting bar.

9. The display device of claim 2,
wherein the second pad is between the first pad and a shorting bar electrically connected to the second pad.

10. The display device of claim 9,
wherein the third pad is overlapped with the first pad and the second pad.

11. The display device of claim 10,
wherein a length in the vertical direction of the third pad is longer than sum of a length in the vertical direction of the first pad and a length in the vertical direction of the second pad.

12. The display device of claim 11,
wherein the second pad is supplied with a reference voltage from the shorting bar via a shorting bar connecting line.

13. The display device of claim 2, further comprising a subpixel, including a light-emitting element and a driving transistor to drive the light-emitting element,
wherein the subpixels are connected to the first line and the second line, supplied with a reference voltage from the first line, and supplied with the data voltage from the second line, and
wherein the first pad electrically connected to the first line is supplied with a voltage to sense the characteristic value of the driving transistor.

14. A display device comprises:
a substrate having a display area where an image is displayed and a non-display area adjacent to the display area;
a source driving integrated circuit configured to supply data voltage to the display area;
a source film electrically connected to the display area and the source driving integrated circuit;
a connecting line;
a first pad overlapping the source film and spaced apart from the source driving integrated circuit; and
a second pad overlapping the source film and connected to the source driving integrated circuit via the connecting line.

15. The display device of claim 14, further comprising:
a subpixel, including a light-emitting element and a driving transistor to drive the light-emitting element;
a first reference pad on the substrate;
a second reference pad on the substrate;
a first reference voltage line electrically connected to the first reference pad and the subpixel;
a shorting bar connecting line electrically connected to the second reference pad;
a data pad on the substrate;
a data line electrically connected to the data pad and the subpixel; and
a shorting bar disposed in the non-display area and electrically connected to the shorting bar connecting line,
wherein the second pad is overlapped with the data pad, and electrically connected to the data pad,
wherein the first pad electrically connects the first reference pad and the second reference pad, and is overlapped with the first reference pad and the second reference pad,
wherein the first reference voltage line and the data line are electrically connected to the subpixel disposed in the display area, and
wherein the shorting bar connecting line is electrically connected to the shorting bar.

16. The display device of claim 15,
wherein a horizontal width of the first pad is longer than a horizontal width of the second pad.

17. The display device of claim 15,
wherein a length in a vertical direction of the first pad is longer than a sum of a length in the vertical direction of the first reference pad and a length in the vertical direction of the second reference pad,
18. The display device of claim 15,
wherein a constant voltage over time is supplied to the shorting bar,
wherein a voltage that varies with time is supplied to the connecting line.

19. A display device comprising:
a display panel including a display area and a non-display area;
a plurality of data lines and reference voltage lines;
a plurality of subpixels electrically connected to the data lines and the reference voltage lines;
a shorting bar configured to receive a reference voltage from an external source;
a source driving integrated circuit configured to supply data voltages to the plurality of subpixels;
a first pad electrically connected to one of the reference voltage lines;
a second pad electrically connected to the shorting bar; and
a third pad overlapping both the first and second pads in a plan view, the third pad electrically disconnected from the source driving integrated circuit.

20. The display device of claim 19, further comprising a source film electrically connected to the display area and the source driving integrated circuit,
wherein the third pad is on the source film.

21. The display device of claim 19, wherein the third pad is larger in surface area than either the first pad or the second pad.

22. The display device of claim 19, wherein the third pad provides an electrical connection between the first pad and the second pad.

23. The display device of claim 19, wherein the third pad overlaps the first pad and the second pad in a stacked manner with an insulating layer interposed between the third pad and the source driving integrated circuit.

24. The display device of claim 20, wherein each subpixel of the plurality of subpixels includes a light-emitting element and a driving transistor to drive the light-emitting element,
wherein, in use, the third pad is configured to be contacted by test equipment for sensing electrical characteristics of the driving transistor prior to bonding of the source film to the display panel.

25. The display device of claim 19, wherein each subpixel of the plurality of subpixels includes a light-emitting element and a driving transistor to drive the light-emitting element, and
wherein, in use, the third pad enables sensing of the driving transistor without using the source driving integrated circuit.

26. The display device of claim 19, further comprising a shorting bar connecting line,
wherein the first pad is positioned between the second pad and the display area in a plan view, and
wherein the second pad is electrically connected to the shorting bar via the shorting bar connecting line.

27. The display device of claim 26, wherein either the shorting bar connecting line or the shorting bar is on a different layer than the reference voltage lines.

28. The display device of claim 26, wherein the shorting bar connecting line is on a different layer than the second pad.

29. The display device of claim 19, wherein the third pad is electrically isolated from the data lines and from all signal lines connected to the source driving integrated circuit.

30. The display device of claim 19, wherein the shorting bar is disposed closer to an edge of the display panel than either the first pad or the second pad.
